(19) United States
(12) Patent Application Publication
(10) Pub. No.: US 2024/0153867 A1
(43) Pub. Date: May 9, 2024

(54) DIAGONAL WIRING LEVEL WITH SKIP-LEVEL VIA CONNECTIONS

(71) Applicant: International Business Machines Corporation, Armonk, NY (US)

(72) Inventors: Nicholas Anthony Lanzillo, Wynantskill, NY (US); Albert M. Chu, Nashua, NH (US); REINALDO VEGA, Mahopac, NY (US); Ruilong Xie, Niskayuna, NY (US); Lawrence A. Clevenger, Saratoga Springs, NY (US); Brent A. Anderson, Jericho, VT (US)

(21) Appl. No.: 17/983,863

(22) Filed: Nov. 9, 2022

(51) Int. Cl. H01L 23/522; H01L 23/528

(52) U.S. Cl. CPC H01L 23/5226; H01L 23/5286

(57) ABSTRACT

A semiconductor structure is provided that includes a device layer and a non-perpendicular (or non-orthogonal) wiring layer that includes a skip-level via that connects this wiring level to the device layer. The skip-level via passes through another wiring layer that is positioned between the non-perpendicular wiring layer and the device layer, without physically contacting any metal lines that are present in this another wiring layer.

### BACKGROUND

The present application relates to semiconductor technology, and more particularly to a semiconductor structure including a non-perpendicular (or non-orthogonal) wiring layer that includes a skip-level via that connects this wiring level to a device layer, while passing through another wiring layer that is positioned between the non-perpendicular wiring layer and the device layer.

In semiconductor technology, a skip-level via (or oftentimes referred to as a “super-Via”) can be formed through many dielectric material layers, bypassing one or more wiring structures within the dielectric material layers, to connect with a lower wiring structure. This provides improved resistance characteristics, minimizes capacitance for a lower wiring structure, as well as provides area efficiencies in the chip manufacturing process.

### SUMMARY

A semiconductor structure is provided that includes a device layer and a non-perpendicular (or non-orthogonal) wiring layer that includes a skip-level via that connects this wiring level to the device layer. The skip-level via passes through another wiring layer that is positioned between the non-perpendicular wiring layer and the device layer, without physically contacting any metal lines that are present in this another wiring layer. The various wiring layers can be located on a frontside of the device layer, on a backside of the device layer, or on both the frontside and the backside of the device layer.

In one aspect of the present application, a semiconductor structure is provided. In one embodiment, the semiconductor structure includes a device layer containing one or more semiconductor devices and at least one device level metal via, a first wiring layer including a plurality of first metal lines, a second wiring layer including a plurality of second metal lines, and at least one first skip-level via connecting the second wiring layer to the device layer. In accordance with the present application, at least one of the first metal lines of the plurality of first metal lines is in direct contact with the at least one device level metal via, the first wiring layer is located between the device layer and the second wiring layer, and the plurality of second metal lines are diagonally orientated relative to the plurality of first metal lines. The diagonal orientation of the second metal lines in the second wiring layer relative to the first metal lines present in the first wiring layer offers a short-distance connection between two points (e.g., input/output) on this structure. For instance, if two transistors are separated by horizontal distance x and vertical distance y, diagonal wiring would enable the shortest-distance connection between them, as opposed to horizontal wiring extending distance x and vertical wiring extending distance y. The at least one first skip-level via provides improved resistance characteristics, minimizes capacitance for the first wiring layer, as well as provides area efficiencies in the chip manufacturing process.

In some embodiments of the present application, the plurality of second metal lines are offset 30° to 60° relative to the plurality of first metal lines. In yet other embodiments of the present application, the plurality of second metal lines are offset 40° to 50° relative to the plurality of first metal lines. These offsets apply for a frontside embodiment of the present application in which the first and second wiring layers are located above the device layer, as well as a backside embodiment in which the first and second wiring layer are located beneath the device layer or embodiments in which the first and second wiring layers are present on both the frontside and the backside of the device layer. This diagonal architecture enables the short distance connection mentioned above.

In some embodiments of the present application, both the first wiring layer and the second wiring layer are located on a frontside of the device layer. This embodiment provides frontside routing of the metal wiring. In the frontside embodiments, the structure can further include at least one first metal via connecting the second wiring layer to the first wiring layer. In the frontside embodiments, the structure can further include a third wiring layer including a plurality of third metal lines. In such embodiments, the third wiring layer is located above the second wiring layer and the third metal lines are orthogonal to the first metal lines. In the frontside embodiments, the structure can further include at least one second skip-level via connecting the third wiring layer to the first wiring layer. In the frontside embodiments, the structure can further include at least one second metal via connecting the third wiring layer to the second wiring layer.

In some embodiments of the present application, both the first wiring layer and the second wiring layer are located on a backside of the device layer. This embodiment provides backside routing of the metal wiring. In the backside embodiments of the present application, the first wiring layer is present in a backside power distribution layer. In the backside embodiments of the present application, the structure can further include at least one first metal via connecting the second wiring layer to the first wiring layer. In the backside embodiments of the present application, the structure can further include a third wiring layer including a plurality of third metal lines. In such embodiments, the third wiring layer is located beneath the second wiring layer and the third metal lines are orthogonal to the first metal lines. In the backside embodiments of the present application, the structure can further include at least one second skip-level via connecting the third wiring layer to the first wiring layer. In the backside embodiments of the present application, the structure can further include at least one second metal via connecting the third wiring layer to the second wiring layer.

In any of the embodiments mentioned above, the second wiring layer is a signal line. In architectures where power delivery is moved to the backside of the chip (“back side power delivery”) then nearly all wiring resources would be devoted to power/ground in order to provide a low-resistance power supply with minimal voltage drop. Having additional wiring resources for signal routing provides an alternative to using wires on the frontside of the chip, which may be congested due to the narrow pitch at lower metal levels. A backside signal wire could provide a low-resistance signal pathway, while also traveling in a direction (diagonally) not traveled by frontside signal wires

In any of the embodiments mentioned above, the one or more semiconductor devices can include at least one transistor. In such embodiments, the at least one device level metal via contacts the at least one transistor.

In any of the embodiments mentioned above, the at least one first skip-level via has a vertical height that is greater than a vertical height of at least one metal via that is present in the structure. The skip-level via of the present application permits the diagonal wiring layer to carry current without shorting the power/ground lines located directly above/below it.

In any of the embodiments mentioned above, each of the plurality of first metal lines, the plurality of second metal lines, the device level metal via, the optional at least one first metal via, the optional at least one second metal via, the at least one first skip via and the optional at least one second skip-level via includes an electrically conductive metal or an electrically conductive metal alloy.

In any of the embodiments mentioned above, the first wiring layer can further include a first dielectric material embedding the plurality of first metal lines, and the second wiring layer further comprises a second dielectric material embedding the plurality of second metal lines. In such embodiments, the at least one first skip-level via passes through the first dielectric material without contact any of the plurality of first metal lines.

### BRIEF DESCRIPTION OF THE DRAWINGS

FIG. 1A is a top down view illustrating an exemplary semiconductor structure of the present application, in this drawing the device layer is not illustrated.

FIG. 1B is a cross sectional view of the exemplary semiconductor structure shown in FIG. 1A.

FIG. 2 is a cross sectional view of an exemplary semiconductor structure in accordance with an embodiment of the present application, in this drawing the device layer is illustrated.

FIG. 3 is a cross sectional view of an exemplary semiconductor structure in accordance with another embodiment of the present application, in this drawing the device layer is not illustrated.

FIG. 4 is a cross sectional view of an exemplary semiconductor structure in accordance with a further embodiment of the present application, in this drawing the device layer is not illustrated.

FIG. 5 is a cross sectional view of an exemplary semiconductor structure in accordance with a yet further embodiment of the present application, in this drawing the device layer is illustrated.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The present application provides a semiconductor structure that includes a device layer and a non-perpendicular (or non-orthogonal) wiring layer that includes a skip-level via that connects this wiring level to the device layer. The skip-level via passes through another wiring layer that is positioned between the non-perpendicular wiring layer and the device layer, without physically contacting any metal lines that are present in this another wiring layer. The various wiring layers can be located on a frontside of the device layer, on a backside of the device layer, or on both the frontside and the backside of the device layer. The various wiring layers of the present application thus provide frontside and/or backside routing of the various metal lines (i.e., wires).

In the present application, the term “frontside” denotes a side of a semiconductor wafer which includes at least one semiconductor device, while the term “backside” denotes a side of the semiconductor wafer that is opposite the side of the semiconductor wafer including the at least one semiconductor device.

In the present application, the term “device layer” denotes a layer of the structure that includes one or more semiconductor devices located on a surface of a semiconductor substrate (or wafer). The semiconductor substrate includes at least one semiconductor material such as, for example, silicon (Si), germanium (Ge) or a silicon germanium alloy (SiGe), having semiconductor properties. The device layer can further include a middle of the line (MOL) dielectric material that includes the at least one device level metal via present therein.

In the present application, the term “semiconductor device” includes, for example, a transistor, capacitor, diode, or any combination thereof. In one example, the semiconductor device is a transistor that includes a source region, a drain region and a gate structure including a gate dielectric material layer and a gate electrode material.

In the present application, the term “skip-level via” denotes a via structure that electrically connects one wiring layer to either a device layer or another wiring layer, while bypassing a wiring layer that is positioned between the skip-level via connected one wiring layer and the device layer and/or between the skip-level via connected one wiring layer and the another wiring layer.

In the present application, the metal lines, i.e., first metal lines M1, second metal lines M2, third metal lines M3, and fourth metal lines M4, as will be mentioned herein below, are each composed of an electrically conductive metal or an electrically conductive metal alloy. Illustrative examples of electrically conductive metals that can be used in providing the metal lines include, but are not limited to, copper (Cu), aluminum (Al), tungsten (W), ruthenium (Ru), or cobalt (Co). Illustrative examples of electrically conductive metal alloys that can be used in the present application to provide the metal lines include, but are not limited to, a Cu—Al alloy, a Cu—W alloy, or Ru—Co alloy. In the present application, each of the various metal lines, i.e., first metal lines M1, second metal lines M2, third metal lines M3, and fourth metal lines M4, as will be mentioned herein below, can be composed of a same electrically conductive material, or at least some of the metal lines, composed of compositionally different electrically conductive materials than remaining metal lines (this embodiment typically applies to metal lines that are present in different wiring layers).

Although not shown in the present application, the metal lines, i.e., first metal lines M1, second metal lines M2, third metal lines M3, and fourth metal lines M4, as will be mentioned herein below, can have a diffusion barrier diffusion barrier liner present on a sidewall and bottom wall thereof, The diffusion barrier liner that can optionally be employed in the present application is composed of a diffusion barrier material that prevents another material from diffusing therethrough. Illustrative examples of diffusion barrier materials that can be used as the diffusion barrier liner include, but are not limited to, Ta, TaN, Ti, TiN, W or WN. In some embodiments, the diffusion barrier liner can include a material stack of two or more diffusion barrier materials. In one example, the diffusion barrier liner can be composed of a stack of Ta/TaN or Ti/TiN. The diffusion barrier liner can have a thickness from 2 nm to 50 nm; although other thicknesses for the diffusion barrier liner are contemplated and can be employed in the present application.

In the present application, the various metal vias, i.e., the device level metal via 14, the silicon-though via 16, the first metal via V1, the second metal via V2 and the third metal via V3, as will be mentioned herein below, are composed of one of the electrically conductive materials as mentioned above for the metal lines. The metal vias and metal lines can be composed of a compositionally same electrically conductive material or a compositionally different electrically conductive material. The metal vias can also include a diffusion barrier liner as mentioned above located on a sidewall and a bottom wall of the metal vias. The diffusion barrier liner can be omitted from the sidewall and bottom of the metal vias.

In the present application, the skip-level vias, i.e., the first skip-level via SV1, and the second skip-level via SV2 mentioned herein below, are composed of one of the electrically conductive materials as mentioned above for the metal lines. The skip-level vias and the metal lines as well as the metal vias can be composed of a compositionally same electrically conductive material or a compositionally different electrically conductive material. The skip-level vias can also include a diffusion barrier liner as mentioned above located on a sidewall and a bottom wall of the metal vias. The diffusion barrier liner can be omitted from the sidewall and bottom of the skip-level vias.

In the present application, various wiring layers, i.e., first wiring layer W1, second wiring layer M2, third wiring layer M3 and fourth wiring layer M4, include at least one metal line as defined above, embedded in at least one dielectric material such as, for example, an interlayer dielectric (ILD) material. The ILD material can include, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” denotes a dielectric material that has a dielectric constant of less than 4.0. All dielectric constants mentioned herein are measured in a vacuum unless otherwise indicated.

In embodiments, a dielectric capping layer can be present between the various wiring layers. When present the dielectric capping layer is composed of a dielectric capping material that is typically compositionally different from the dielectric material that provides the wiring layer. Illustrative examples of dielectric capping materials that can be employed in the present application include, but are not limited to, silicon carbide, silicon nitride, silicon oxide, a carbon doped oxide, a nitrogen and hydrogen doped silicon carbide (SiC(N,H)) or a multilayered stack of at least one of the aforementioned dielectric capping materials.

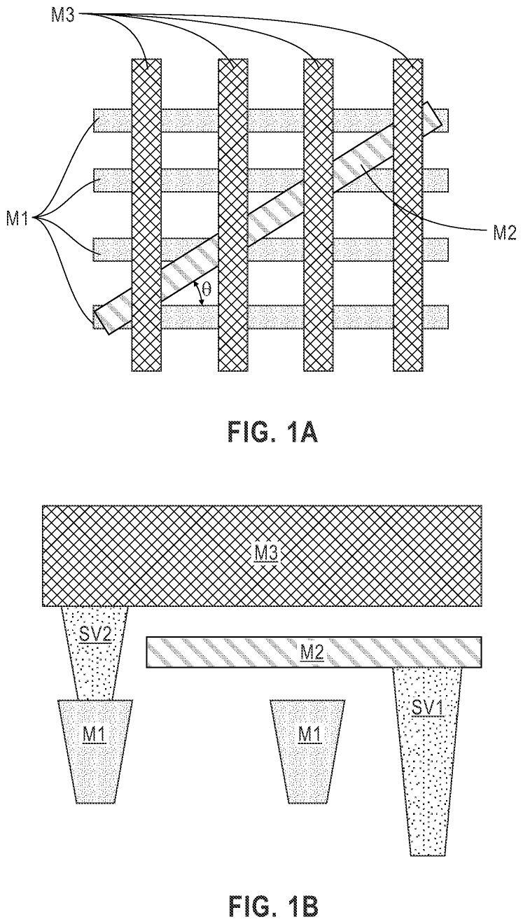

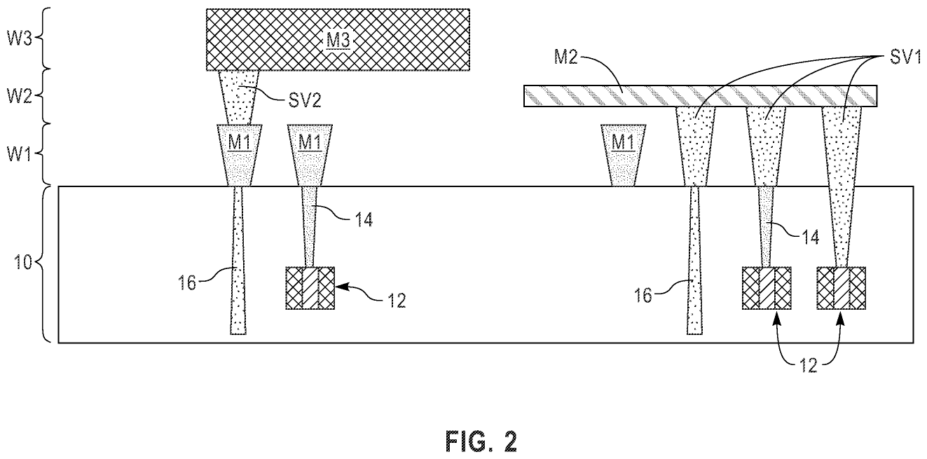

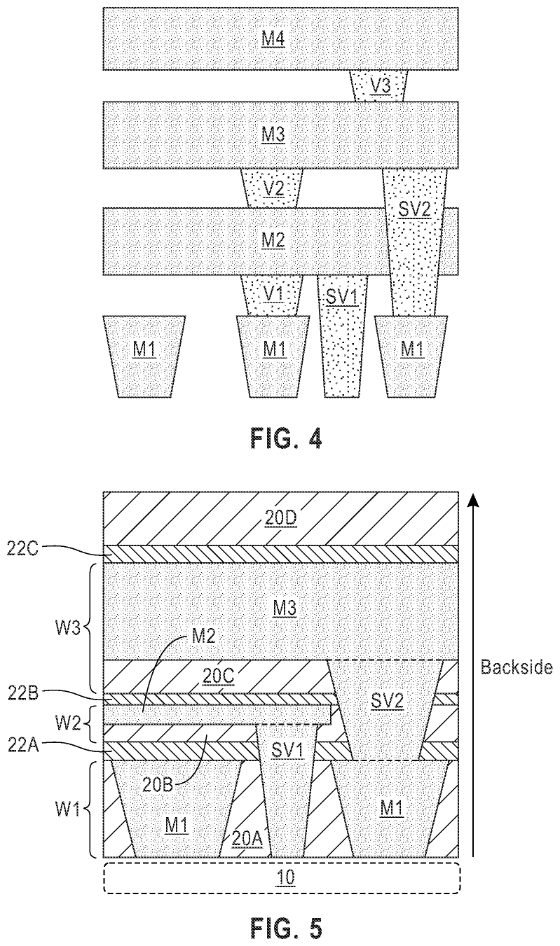

Reference is now made to FIGS. 1A, 1B and 2 which illustrate an exemplary semiconductor structure of the present application, in FIGS. 1A-1B the device layer is not illustrated, but the device layer 10 is shown in FIG. 2. In the illustrated embodiment shown in FIGS. 1A, 1B and 2 the various wiring layers are located on a frontside of the device layer 10; the same wiring structure can also be used on the backside of the device layer 10 (this aspect of the present application will become apparent from FIG. 5 of the present application).

Notably, FIGS. 1A, 1B and 2 illustrate a semiconductor structure that includes a device layer 10 containing one or more semiconductor devices 12 and at least one device level metal via 14, a first wiring layer W1 including a plurality of first metal lines M1, wherein at least one of the first metal lines M1 is in direct contact with the at least one first device level metal via 14, and a second wiring layer W2 including a plurality of second metal lines M2 (one or which is shown in FIGS. 1A-1B and 2), wherein the first wiring layer W1 is located between the device layer 10 and the second wiring layer W2, and the plurality of second metal lines M2 are diagonally orientated (see, angle ⊖ shown in FIG. 1A) relative to the plurality of first metal lines M1 (see, for example FIG. 1A). Note that the various wiring layers of the present application can also be referred to as a wiring (or metal) level.

The structure shown in FIGS. 1A, 1B and 2 further includes at least one first skip-level via SV1 connecting the second wiring layer M2 to the device layer 10. Notably, the at least one first skip-level via SV1 connects one of the second metal lines M2 present in the second wiring layer W2 to the device layer 10. FIG. 2 illustrates three first skip-level vias SV1 in which one of the first skip-level vias SV1 contacts a through-silicon via structure 16, another of the first skip-level vias SV1 contacts another device level metal via 14 that is in contact with one of the semiconductor devices 12, and a yet another of the first skip-level via SV1 that directly contacts one of the semiconductor devices 12. In the present application, at least one of these connections between the first skip-level via SV1 and the device layer 10 is present.

The structure shown in FIGS. 1A, 1B and 2 can further include a third wiring layer W3 including a plurality of third metal lines M3, wherein the third wiring layer W3 is located above the second wiring layer W2 and each of the third metal lines M3 is orthogonal (i.e., perpendicular) to each of the first metal lines M1. In some embodiments, and as is illustrated in FIGS. 1B and 2, the structure further includes at least one second skip-level via SV2 that connects the third wiring layer W3 to the first wiring layer W1. Notably, the at least second skip-level via SV2 electrically connects one of the third metal liners M3 to one of the first metal lines M1. In some embodiments, the second skip-level via SV2 can be omitted.

As mentioned above and as is illustrated in FIG. 1A, the plurality of second metal lines M2 are diagonally orientated relative to the plurality of first metal lines M1. Notably, the plurality of second metal lines M2 are offset by angle θ from the plurality of first metal lines M1. In one embodiment, this offset angle is from 30° to 60°. In yet another embodiment, this offset angle is from 40° to 50°, with an offset of 45° being more typical. The orthogonal wiring layers typically form a mesh pattern with equal dimensions in the horizontal/vertical directions. Thus, a 45° angle would enable the most flexibility in finding the “openings” in the mesh structure. However, other angles within the ranges mentioned herein can be used depending on the relative sizes of the orthogonal wiring layers above/below.

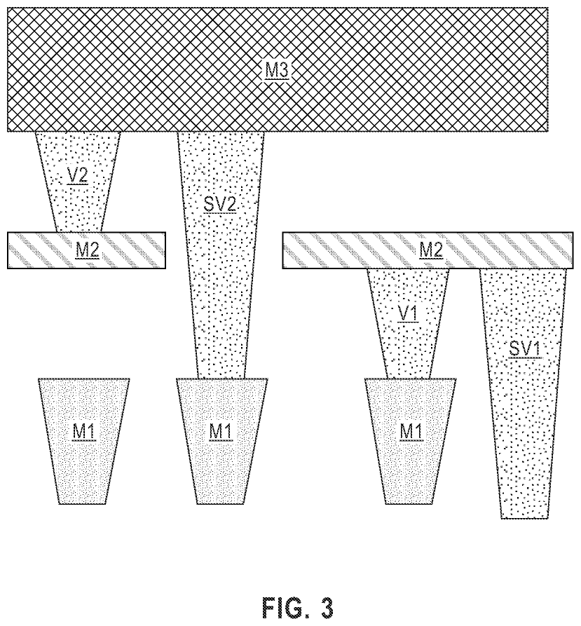

Reference is now made to FIG. 3, which illustrates an exemplary semiconductor structure in accordance with another embodiment of the present application, in this drawing the device layer 10 is not illustrated. The illustrated embodiment can be used on the frontside and/or the backside of the device layer 10. The exemplary semiconductor structure shown in FIG. 3 is similar to the semiconductor structure illustrated in FIG. 1B except that the exemplary structure shown in FIG. 3 includes a first metal via V1 connecting the second wiring layer W2 to the first wiring layer W1, and a second metal via V2 connecting the third wiring layer W3 to the second wiring layer W2. Notably, the first metal via V1 connects one of the second metal lines M2 to one of the first metal lines M1, while the second metal via V2 connects one of the third metal lines M3 to one of the second metal lines M2. It is noted that the first metal via V1 and/or the second metal via V2 are optional via structures that are not required in all instances. In embodiments of the present application, the first metal via V1 is present, but not the second metal via V2. In embodiments of the present application, the second metal via is present, but not the first metal via V1. In yet other embodiments, the first metal via V1 and the second metal via V2 are both present.

Reference is now made to FIG. 4, which illustrates an exemplary semiconductor structure in accordance with a further embodiment of the present application, in this drawing the device layer 10 is not illustrated. The illustrated embodiment can used on the frontside and/or the backside of the device layer 10. The exemplary structure shown in FIG. 4 shows an embodiment similar to the one shown in FIG. 3 and further including a fourth wiring layer including a plurality of fourth metal lines M4. The fourth metal lines M4 are orientated in a same direction as the first metal lines M1 and thus are orthogonal, (i.e., perpendicular) to the third metal lines M3. The illustrated structure further includes a third metal via V2 connecting the fourth wiring layer to the third wiring layer; notably, the third metal via V3 connects one of the fourth metal lines to one of the third metal lines M3. It is noted that in this exemplary structure, the first metal via V1 and/or the second metal via V2 can be optional components.

Reference is now made to FIG. 5, which illustrates an exemplary semiconductor structure in accordance with a yet further embodiment of the present application, in this drawing the device layer 10 is illustrated. The exemplary structure shown in FIG. 5 is for an embodiment in which the first wiring layer W1, the second wiring layer W2 and the third wiring layer W3 are located on a backside of the device layer 10. In this embodiment, the first wiring layer W1 is a first backside wiring layer, the second wiring layer W2 is a second backside wiring layer, and the third wiring layer is a third backside wiring layer.

The structure illustrated in FIG. 5 includes device layer 10 containing one or more semiconductor devices (not shown) and at least one device level metal via (not shown, the device level metal via would extend from the backside surface of the semiconductor substrate to the semiconductor device that is present in the device level), a first wiring layer W1 including a plurality of first metal lines M1, wherein at least one of the first metal lines M1 is in direct contact with the at least one first device level metal via, and a second wiring layer W2 including a plurality of second metal lines M2, wherein the first wiring layer W1 is located between the device layer 10 and the second wiring layer W2, and the plurality of second metal lines M2 are orientated diagonally to the plurality of first metal lines M1.

The structure shown in FIG. 5 further includes at least one first skip-level via SV1 connecting the second wiring layer M2 to the device layer 10. Notably, the at least one first skip-level via SV1 connects one of the second metal lines M2 present in the second wiring layer W2 to the device layer 10. The structure shown in FIG. 5 can further include a third wiring layer W3 including a plurality of third metal lines M3, wherein the third wiring layer W3 is located above the second wiring layer W2 and each of the third metal lines M3 is orthogonal (i.e., perpendicular) to each of the first metal lines M1.

In some embodiments, and as is illustrated in FIG. 5, the structure further includes at least one second skip-level via SV2 that connects the third wiring layer W3 to the first wiring layer W1. Notably, the at least second skip-level via SV2 electrically connects one of the third metal lines M3 to one of the first metal lines M1. In some embodiments, the second skip-level via SV2 can be omitted. In this backside embodiment, the first wiring layer W1 can be part of a backside power distribution layer which can distribute power to the one or more semiconductor devices present in the device layer.

Although not illustrated the structure shown in FIG. 5 can also include a first via structure and/or a second via structure as mentioned above.

In FIG. 5, the first wiring layer W1 includes a first dielectric material layer 20A (including one of the ILD materials mentioned above) embedding the first metal lines M1, a first dielectric capping layer 22A, a second dielectric material layer 20B (including one of the ILD materials mentioned above) embedding the second metal lines M2, a second dielectric capping layer 22B, a third dielectric material layer 20C (including one of the ILD materials mentioned above) embedding the third metal lines M2, a third dielectric capping layer 22C, and a fourth dielectric material layer 20D. The various dielectric materials can be present in any of the semiconductor structures illustrated in FIGS. 1A-4 above.

In any of FIGS. 1A-5, the second wiring layer W2 can be configured to connect a signal from a first device layer point to a second device layer point. Transistors (devices) need to be connected to one another in order to perform digital logic operations. Thus, the output of one transistor typically drives the input of another transistor, or series of transistors. The wiring connecting the two (or more) transistors is referred to as signal wiring and is typically done on the frontside of the chip. Providing additional signal routing on the backside of the chip allows for design flexibility and a potentially lower-resistance connection between devices.

In any of FIGS. 1A-5, the at least one first skip-level via SV1 has a vertical height that is greater than a vertical height of at least one of the metal vias, i.e., first metal via or second metal via, that is present in the structure. In one embodiment of the present application, the vertical height of the at least one first skip-level via is from 10 nm to 100 nm, while the vertical height of the at least one metal via is from 10 nm to 50 nm. The skip-level via enables electrical connection to the diagonal wiring layer without shorting to the wiring layer immediately above/below the diagonal wiring layer.

The semiconductor structure of the present application can be formed utilizing frontside and/or backside metallization techniques that are well known to those skilled in the art. For example, the structure can be formed by first forming a device layer 10 that includes one or more semiconductor devices 12 and at least one device level metal via 14. The device layer 10 can be formed utilizing conventional front-end-of-the-line (FEOL) and middle-of-the-line (MOL) device processing techniques that are well known to those skilled in the art. In embodiments in which the wiring layers are formed on the backside of the device layer 10 wafer flipping and removal of at least a portion of the semiconductor substrate can be performed prior to forming the various wiring layers. Each wiring layer is formed by first depositing a dielectric material (i.e., the ILD material mentioned above). At least one opening can then be formed into the deposited dielectric material (by lithography and etching) and thereafter a metal line is formed into each opening by deposition of an electrically conductive material, as defined above, followed by a planarization process (e.g., chemical mechanical polishing). An optional dielectric capping layer can be formed on the wiring layer after processing the same to include the metal lines. The various wiring layers are configurated such that the second metal lines are diagonally orientated relative to the first metal lines and the third metal lines are orthogonally orientated relative to first metal lines. The skip-level vias and the metal vias can be formed by forming a via opening (includes lithography and etching) and then filling the via open with an electrically conductive material (includes deposition and planarization).

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor structure comprising:
a device layer comprising one or more semiconductor devices and at least one device level metal via;
a first wiring layer comprising a plurality of first metal lines, wherein at least one of the first metal lines of the plurality of first metal lines is in direct contact with the at least one device level metal via;
a second wiring layer comprising a plurality of second metal lines, wherein the first wiring layer is located between the device layer and the second wiring layer, and the plurality of second metal lines are diagonally orientated relative to the plurality of first metal lines; and
at least one first skip-level via connecting the second wiring layer to the device layer.

2. The semiconductor structure of claim 1, wherein the plurality of second metal lines are offset 30° to 60° relative to the plurality of first metal lines.

3. The semiconductor structure of claim 2, wherein the plurality of second metal lines are offset 40° to 50° relative to the plurality of first metal lines.

4. The semiconductor structure of claim 1, wherein both the first wiring layer and the second wiring layer are located on a frontside of the device layer.

5. The semiconductor structure of claim 4, further comprising at least one first metal via connecting the second wiring layer to the first wiring layer.

6. The semiconductor structure of claim 4, further comprising a third wiring layer comprising a plurality of third metal lines, wherein the third wiring layer is located above the second wiring layer and each of the third metal lines is orthogonal to each of the first metal lines.

7. The semiconductor structure of claim 6, further comprising at least one second skip-level via connecting the third wiring layer to the first wiring layer.

8. The semiconductor structure of claim 7, further comprising at least one second metal via connecting the third wiring layer to the second wiring layer.

9. The semiconductor structure of claim 1, wherein both the first wiring layer and the second wiring layer are located on a backside of the device layer.

10. The semiconductor structure of claim 9, wherein the first wiring layer is present in a backside power distribution layer.

11. The semiconductor structure of claim 9, further comprising at least one first metal via connecting the second wiring layer to the first wiring layer.

12. The semiconductor structure of claim 11, further comprising a third wiring layer comprising a plurality of third metal lines, wherein the third wiring layer is located beneath the second wiring layer and each of the third metal lines is orthogonal to each of the first metal lines.

13. The semiconductor structure of claim 12, further comprising at least one second skip-level via connecting the third wiring layer to the first wiring layer.

14. The semiconductor structure of claim 13, further comprising at least one second metal via connecting the third wiring layer to the second wiring layer.

15. The semiconductor structure of claim 1, wherein the second wiring layer is a signal line.

16. The semiconductor structure of claim 1, wherein the one or more semiconductor devices comprise at least one transistor.

17. The semiconductor structure of claim 16, wherein at least one device level metal via is in direct contact with the at least one transistor.

18. The semiconductor structure of claim 1, wherein the at least one first skip-level via has a vertical height that is greater than a vertical height of at least metal via that is present.

19. The semiconductor structure of claim 1, wherein each of the plurality of first metal lines, the plurality of second metal lines, the at least one device level metal via and the at least one first skip via comprises an electrically conductive metal or an electrically conductive metal alloy.

20. The semiconductor structure of claim 1, wherein the first wiring layer further comprises a first dielectric material embedding the plurality of first metal lines, and the second wiring layer further comprises a second dielectric material embedding the plurality of second metal lines, wherein the at least one first skip-level via passes through the first dielectric material without contact any of the plurality of first metal lines.
